(19) United States
(12) Patent Application Publication
(10) Pub. No.: US 2004/0196697 A1
(43) Pub. Date: Oct. 7, 2004

(54) Method of improving surface mobility before electroplating

(76) Inventors: Ted Ko, Taipei (TW); Ming-Hsing Tsai, Taipei (TW)

Correspondence Address: DUANE MORRIS, LLP, IP DEPARTMENT, ONE LIBERTY PLACE, PHILADELPHIA, PA, 19103-7396, US

(21) Appl. No.: 10/407,129

(22) Filed: Apr. 3, 2003

(51) Int. Cl. G11C 11/34

(52) U.S. Cl. 365/185.05; 205/210; 205/215

(57) ABSTRACT

The present invention provides a method of improving surface mobility of a metal seed layer on a wafer before electroplating comprising applying a solvent to a surface of the metal seed layer.

### FIELD OF THE INVENTION

The present invention relates to integrated circuits and more particularly to a method of improving surface mobility of a metal seed layer before electroplating and an integrated circuit manufactured thereby.

### DESCRIPTION OF RELATED ART

The development of semiconductor manufacturing technology continuously increases the operating speed and decreases the size of integrated circuits. An integrated circuit, comprising many electronic components such as transistors and capacitors, is typically formed by multiple levels of interconnects. Patterned conductive material on one interconnect level is electrically insulated from patterned conductive material on another interconnect level by a layer of dielectric material such as silicon dioxide. Different levels of interconnects are electrically connected with each other by structures often referred to as vias or contacts.

The interconnects on each level and vias used to connect different levels are conventionally formed by aluminum or aluminum alloy. Traditionally, a layer of aluminum or aluminum alloy is deposited on the top of a dielectric layer. After photomasking, all aluminum is etched away except the patterned interconnects and vias. In order to increase the operating speed of integrated circuits while reducing power consumption, conductive material with lower electrical resistance such as copper is used to replace aluminum. However, copper is difficult to etch in a semiconductor environment. As a result, a damascene approach, comprising of etching openings such as trenches and vias in the dielectric material and filling with conductive material, is used. The bulk of the copper trench-fill and via-fill is often done applying an electroplating technique.

For conductive materials such as copper, to be deposited by electroplating, a copper seed layer is deposited on the top of a metal barrier layer overlying the openings for trenches or vias. The copper seed layer is deposited on the integrated circuit to act as an cathode electrode for the electroplating process. The wafer is then immersed in an electrolyte solution containing copper ions. An electrical current is then passed through the copper seed layer, the wafer and the electrolyte solution to cause the deposition of copper on the surface of copper seed layer.

Because of the decrease in size of lines on the interconnect and vias used to vertically integrate different layers of interconnect, it is important to have a high quality of electroplating to ensure proper electrical connections. However, when copper seeds are exposed in the air before electroplating, the surface mobility deteriorates and the quality of electroplating decreases.

### SUMMARY OF THE INVENTION

The present invention provides a method of improving surface mobility of a metal seed layer on an integrated circuit before electroplating, comprising applying a solvent to a surface of the metal seed layer.

### BRIEF DESCRIPTION OF THE DRAWINGS

A more complete understanding of the present invention can be obtained by reference to the detailed description of embodiments in conjunction with the accompanying drawing, in which:

FIG. 1 schematically illustrates a plan view of a dual damascene structure for electroplating.

FIG. 2 schematically illustrates a plan view of application a solvent on a wafer.

FIG. 3 schematically illustrates a plan view of removing superfluous solvent by spinning.

### DETAILED DESCRIPTION OF THE INVENTION

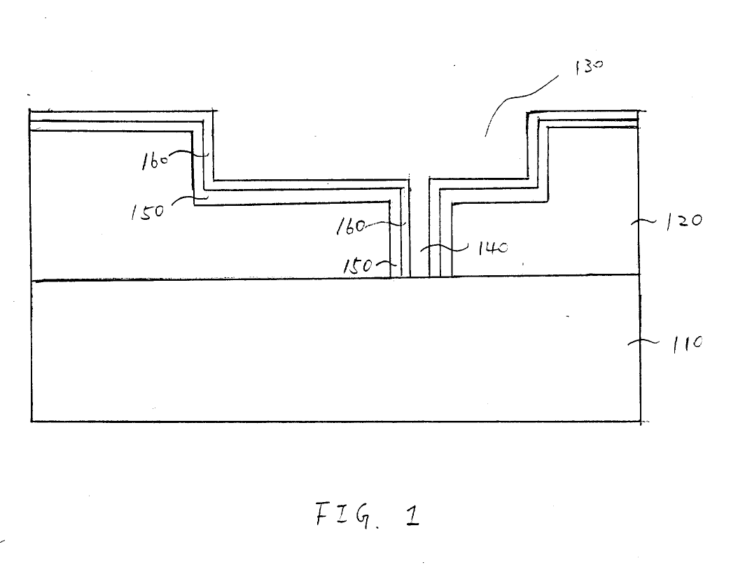

Referring to FIG. 1, a dielectric layer 120 is formed over a conductive interconnection layer 10. In some embodiments, layer 10 can be a semiconductor substrate or wafer. In a dual damascene process, through photomasking and etching, a trench 130 and a via 140 are formed. A thin barrier metal layer 150 is formed by materials such as tantalum (Ta) or tantalum nitride (TaN) to prevent the diffusion of copper. A metal seed layer 160 is then formed over the barrier metal layer 150 by, for example, physical vapor deposition (PVD) or chemical vapor deposition (CVD). In one embodiment, copper is used as a conductive material to fill trenches and vias by electroplating. Thus, the metal seed layer 160 can be a copper seed layer. In other embodiments, when aluminum, silver, or gold is used as conductive materials, the metal seed layer is an aluminum, silver, or gold layer.

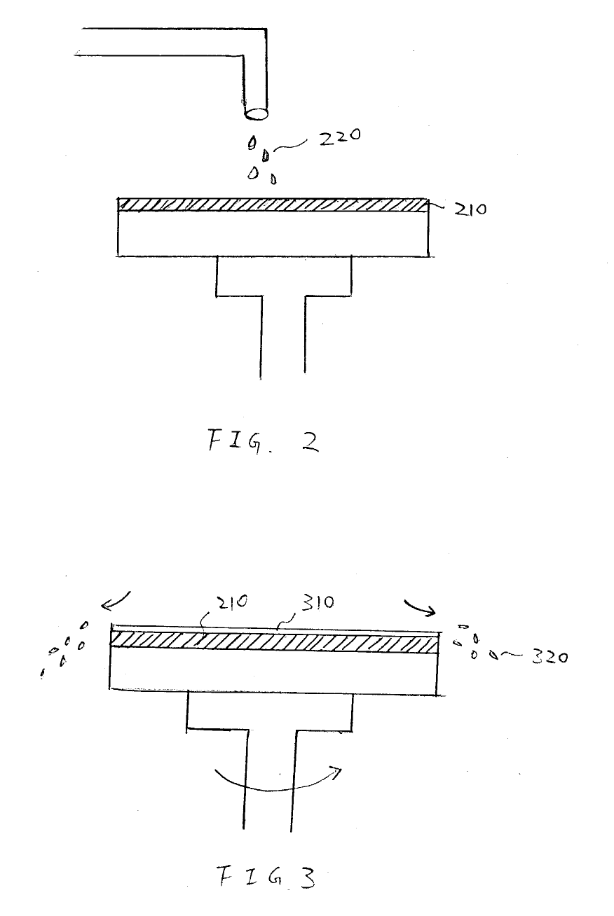

Before electroplating, as shown in FIG. 2, a solvent 220 such as de-ionized water or an organic solvent, for example polyethylene glycol, is applied over the metal seed layer 160. In one embodiment, the wafer 210 rotated slowly, while the solvent 220 is applied, to substantially uniformly distribute the solvent 220 over the surface of the metal seed layer 160. The solvent cleans up copper dioxide and contamination such as dust and particles. As illustrated in FIG. 3, the wafer 210 on which metal seed layer 160 is deposited is then spun to remove superfluous solvent 320 from the surface of metal seed layer 160. Through the process of spinning, any dust or other contamination attached on the surface of metal seed layer 160 is substantially washed away with superfluous solvent 320. A thin film of the solvent 310 is formed on the surface of metal seed layer 160 to improve the surface mobility enabling the electrolyte solution containing metal ions such as copper ions to more uniformly contact the surface of metal seed layer 160; thus promoting the growth of the conductive material such as copper to fill the trench 130 and other features with very small dimension such as the via 140.

After the wafer 210 is immersed into electrolyte solution, any solvent 310 which remains on the surface of metal seed layer 160 becomes part of the electrolyte solution; and, depending upon the concentration of the remaining solvent, could dilute the electrolyte. When dilution occurs, the electrolyte solution has to be restored to its predetermined composition. Thus, one advantage of applying organic solvents is to reduce costs of restoring the electrolyte solution because most organic solvents have higher evaporation rate than de-ionized water. Thus, less amount of organic solvent will be left on the wafer surface to change the composition of the electrolyte solution. Moreover, the electrolyte solution contains some additives which are organic compounds in most cases. Thus, applying organic solvents with the same compounds as that of electrolyte solution has less of an adverse effect in the composition of electrolyte solution. Finally, based on characteristics such as surface energy and wettability, some organic solvents, are more uniformly distributed over the surface of metal seed layer 160, and have better effect on both removing copper dioxide and contamination.

The metal seed layer 160 together with the wafer is mechanically clamped to a cathode electrode to establish an electrical contact. The metal seed layer 160 together with the wafer is then immersed into an electrolyte solution containing metal ions such as copper ions. An electrical current is then passed through the wafer-electrolyte system to cause reduction and deposition of conductive material such as copper on the surface of metal seed layer 160. Subsequent planarization processing, such as chemical mechanical polishing (CMP), removes unwanted portions of the metal blanket layer formed during electroplating, resulting in the desired patterned metal layer in a semiconductor integrated circuit being formed.

While specific embodiments of the present invention are described in details as above, people skilled in the art will appreciate that numerous variations and modifications of these embodiments fall within the scope of the invention as defined in the following claims.

What is claimed is:

1. A method of improving surface mobility of a metal seed layer in an integrated circuit before electroplating, comprising:
applying a solvent to a surface of said metal seed layer.

2. The method of claim 1 further comprising:
removing superfluous solvent from the surface of said metal seed layer.

3. The method of claim 1 wherein said metal seed layer is copper.

4. The method of claim 1 wherein said solvent is de-ionized water.

5. The method of claim 1 wherein said solvent is organic solvent.

6. The method of claim 1 wherein said solvent is polyethylene glycol.

7. The method of claim 1 wherein said metal seed layer is copper and said solvent is de-ionized water.

8. The method of claim 7 further comprising:
removing superfluous solvent from the surface of said metal seed layer.

9. A method of improving surface mobility of a metal seed layer in an integrated circuit, comprising:
applying a solvent to a surface of said metal seed layer;
removing superfluous solvent from the surface of said metal seed layer;
immersing said metal seed layer in an appropriate electrolyte solution; and
electroplating.

10. The method of claim 9 wherein said metal seed layer is copper.

11. The method of claim 9 wherein said solvent is de-ionized water.

12. The method of claim 9 wherein said solvent is organic solvent.

13. The method of claim 9 wherein said solvent is polyethylene glycol.

14. The method of claim 9 wherein said metal seed layer is copper and said solvent is de-ionized water.

15. An integrated circuit manufactured by the method of claim 1.

16. The integrated circuit of claim 15 wherein superfluous solvent is removed from the surface of said metal seed layer.

17. The integrated circuit of claim 15 wherein said metal seed layer is immersed in an appropriate electrolyte solution and electroplates.

18. The integrated circuit of claim 15 wherein said metal seed layer is copper.

19. The integrated circuit of claim 15 wherein said solvent is de-ionized water.

20. The integrated circuit of claim 15 wherein said solvent is organic solvent.

21. The integrated circuit of claim 15 wherein said solvent is polyethylene glycol

22. The integrated circuit of claim 15 wherein said metal seed layer is copper and said solvent is de-ionized water.

23. The integrated circuit of claim 22 wherein:
superfluous solvent is removed from the surface of said metal seed layer; and
said metal seed layer is immersed in an appropriate electrolyte solution and electroplates.
